(19) United States
(12) Patent Application Publication
(10) Pub. No.: US 2010/0155903 A1
(43) Pub. Date: Jun. 24, 2010

(54) Annealed wafer and method for producing annealed wafer

(75) Inventors: Kazunori Ishisaka, Yamaguchi (JP); Katsuhiko Nakai, Yamaguchi (JP); Masayuki Fukuda, Yamaguchi (JP)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 12/653,156

(22) Filed: Dec. 9, 2009

(30) Foreign Application Priority Data
Dec. 18, 2008 (JP) 2008-322874

(51) Int. Cl. H01L 29/32; H01L 21/26

(52) U.S. Cl. 257/617; 438/473; 257/E29.107; 257/E21.328

(57) ABSTRACT

An annealed wafer having enhanced gettering effects for Cu is produced by heating a silicon substrate containing a nitrogen concentration of 5×10¹⁴ to 1×10¹⁶/cm³, a carbon concentration of 1×10¹⁵ to 5×10¹⁶/cm³, and an oxygen concentration of 6×10¹⁷ to 11×10¹⁷/cm³ at a temperature of 650 to 800° C. for a time ≧4 hours, and subjecting the heated substrate to argon annealing at a temperature of 1100 to 1250° C., wherein internal stacking fault density after annealing is ≧5×10⁸/cm³.

### CROSS-REFERENCE TO RELATED APPLICATIONS

This application claims priority to Japanese Patent Application No. 2008-322874 filed Dec. 18, 2008, which is herein incorporated by reference.

### BACKGROUND OF THE INVENTION

1. Field of the Invention

The present invention relates to an annealed wafer and a method for producing an annealed wafer.

2. Background Art

A semiconductor substrate, in particular, a silicon single crystal wafer (hereinafter also referred to simply as a “substrate”) has been used as a substrate for the production of highly-integrateds MOS devices. Most silicon single crystal wafers are substrates cut from an ingot of silicon single crystal produced by the Czochralski (CZ) method.

In such a silicon single crystal wafer, oxygen entrained during production of the single crystal is present in a supersaturated state, which will deposit in a subsequent device process to form oxygen precipitates (a silicon oxide deposit commonly known as “BMD”: Bulk Micro Defect) inside the substrate. Generation of oxygen precipitates in an activated region of the device has been known to deteriorate device characteristics, such as a decrease in voltage resistance of a gate oxidized film, or increase in junction leak current, while the generation of the oxygen precipitates in the bulk other than in the activated region of the device effectively acts as a gettering source to capture contamination of heavy metals entrained during device processing, and also functions to maintain cleanliness of the substrate surface, which is the device activated layer.

Intrinsic gettering (IG) uses such effects technically, and has been used to prevent deterioration of device characteristics caused by heavy metal contamination. Therefore, silicon single crystal wafers have been required to generate a moderate number of oxygen precipitates during the device fabrication process.

In response to these requirements, various approaches have been tried. For example, nitrogen doping has been carried out in growing silicon single crystals by the CZ method, whereby grown-in defects are suppressed as well as promoting oxygen precipitation. By subjecting a mirror wafer obtained by slicing and polishing the nitrogen doped silicon single crystal to heat treatment with argon gas, hydrogen gas, and the like at high temperature (1100 to 1350° C.) for an extended period (“annealing”), a silicon semiconductor substrate (“annealed wafer”), which attains both surface layer integrity and an increase in oxygen precipitation nuclei density in the bulk can be produced. It is known that annealed wafers of such an IG material (mainly composed of the oxygen precipitates) has gettering capability for heavy metal impurities.

However, according to a report of Kazuyuki Bokusawa, Jiro Yosigami, “Deterioration of device reliability caused by Cu contamination in a production process of a semiconductor, and its mechanism”: A technological research report (Communication Institute Technology Report), SDM2002-188 (October, 2002), of The Institute of Electronics, Information and Communication Engineers, published by Aggregate Corporation, The Institute of Electronics, Information and Communication Engineers, as shown in FIG. 1, even the IG material has weak gettering effects for Cu, a common wiring material of high rate devices, and exhibits deterioration of device reliability caused by Cu contamination from re-discharge of gettered Cu even during heat treatment in device processes at a low temperature (about 400° C.), like a wiring step.

In addition, in a conventional DZ-IG wafer (DZ: Denuded Zone), 3-stage heat treatments have been practiced. IG effects have been obtained by subjecting a CZ substrate with high oxygen concentration to heat treatment at 3-stages, that is, at high temperature (about 1100° C.), at low temperature (about 650° C.) and at intermediate temperature (about 1000° C.). However, even in a wafer obtained by subjecting the conventional DZ-IG wafer to 3-stage heat treatments, there is still a problem of weak gettering effects for Cu, and thus deterioration of device reliability caused by Cu contamination due to re-discharging of gettered Cu, even at low temperatures (400° C.) like a wiring step.

### SUMMARY OF THE INVENTION

It is an object of the present invention to improve upon the art discussed above and to provide an annealed wafer with enhanced gettering effects for Cu, and to provide a method for producing the annealed wafer. These and other objects are achieved by an annealed wafer, characterized in that oxygen precipitates with a size of 10 nm to 120 nm are present in a number ≧5×10¹¹/cm³, and a stacking fault density is ≧5×10⁸/cm³, at a position equal to or deeper than 50 μm from the surface of the silicon wafer, and a method for producing the annealed wafers comprising heating a silicon substrate containing nitrogen at a concentration of 5×10¹⁴ to 1×10¹⁶/cm³, a carbon concentration of 1×10¹⁵ to 5×10¹⁶/cm³, and an oxygen concentration of 6×10¹⁷ to 11×10¹⁷/cm³ at a temperature of 650 to 800° C. for a time 4 hours, and subjecting the heated substrate to argon annealing at a temperature of 1100 to 1250° C., wherein internal stacking fault density after annealing is equal to or higher than 5×10⁸/cm³.

### BRIEF DESCRIPTION OF THE DRAWINGS

FIG. 1 is a drawing showing the relationship between Cu gettering capability and heat treatment temperature, in the case where a low temperature heat treatment in air was conducted after a heat treatment at 950° C. for 5 minutes in a nitrogen atmosphere, on a CZ-IG wafer excerpted from data reported in Bokusawa, op. cit.

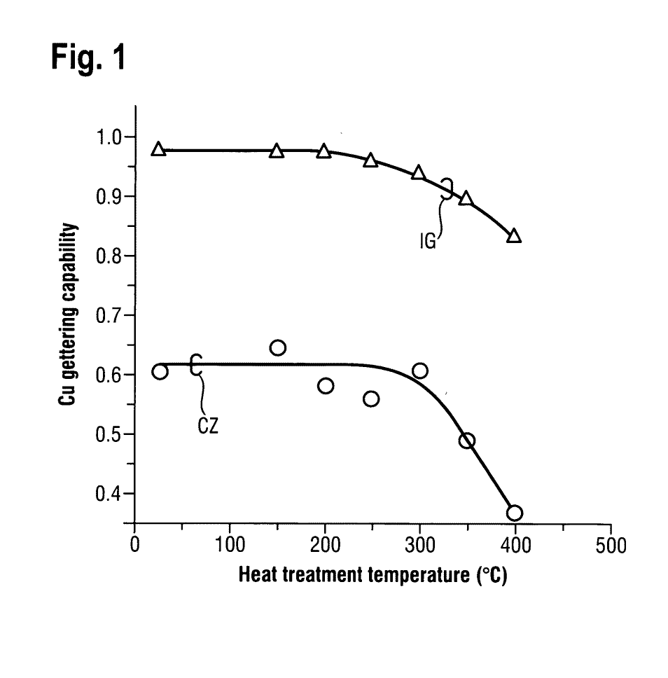

FIG. 2 is a drawing showing a cross-section of an annealed wafer observed with an optical microscope, the wafer having been obtained by cleaving the annealed wafer of Example 1 and subjecting the cleaved wafer to light etching for 2 minutes to a depth of 100 μm from the surface.

### DETAILED DESCRIPTION OF THE PREFERRED EMBODIMENT(S)

According to the present invention, there is provided an annealed wafer, which is capable of enhancing the gettering effects for Cu, suppressing re-discharging of gettered Cu even in heat treatment in a device process at a low temperature, preventing Cu contamination, and enhancing device reliability; and a method for producing the annealed wafer.

Explanation will be given below on preferred embodiments of the present invention, accompanied by reference to the drawings.

### I. Method for Producing Annealed Wafers

A method for producing an annealed wafer relevant to the present invention comprises heating a silicon substrate having a nitrogen concentration of 5×10¹⁴ to 1×10¹⁶/cm³, a carbon concentration of 1×10¹⁵ to 5×10¹⁶/cm³, and an oxygen concentration of 6×10¹⁷ to 11×10¹⁷/cm³ at a temperature of 650 to 800° C. for ≧4 hours (hereinafter referred to as “heat treatment step”), and (2) subjecting the heated substrate to argon annealing at a temperature of 1100 to 1250° C. (hereinafter referred to as “annealing step”), wherein internal stacking fault density after annealing is 5×10⁸/cm³, and the surface layer is free of faults. According to the production method, the stacking faults can be formed around a micro defect (BMD) composed of oxygen precipitates (nuclei) of IG material (mainly composed of the oxygen precipitates). Therefore, by making the stacking fault a gettering site for Cu, gettering effects for Cu, in particular, low temperature (e.g. 400° C.) re-discharge of Cu which has been gettered during cooling after high temperature treatment, (e.g. 400° C.) can be suppressed. In addition, owing to gettering capability manifested by the oxygen precipitates (nuclei) of the IG material, excellent gettering capability for impurities such as other heavy metals can be provided.

Explanation will now be given below for each of the constituents of the invention.

### (1) Heat Treatment Step

(a) Silicon Substrate

A silicon substrate to be used in the heat treatment step may be prepared by adjusting the concentration of nitrogen, carbon and oxygen in growing silicon single crystals by the CZ method. As a result of nitrogen doping, a fault formed during crystal growth, what is called a “void grown-in fault”, can be made smaller, and by subsequently annealing with an argon gas, subsequently, not only surface voids can be eliminated but also an ingot of silicon single crystal having oxygen precipitation capability can be produced. The higher the nitrogen concentration, the more the oxygen precipitation density increases. This is because the addition of nitrogen forms oxygen precipitation nuclei which are stable even at a high temperature in the silicon substrate, which thus remain even after annealing at a high temperature (1100 to 1250° C.). In an annealed wafer still having oxygen precipitation nuclei retained in the silicon substrate, oxygen precipitates are formed by heat treatment in subsequent device processing steps. The number of oxygen precipitation nuclei stable even at a high temperature depends on the nitrogen concentration. Therefore, an increase in the nitrogen concentration will increase oxygen precipitation density. In addition, by controlling a carbon doping or carbon amount, BMD in the present invention can be formed in the number exceeding 5×10¹¹/cm³. Still more, by controlling the oxygen doping or oxygen amount, BMD in a number exceeding 5×10¹¹/cm³ and with a size of 10 nm to 120 nm can be formed. Thus, the mirror polished wafer (silicon substrate) of the invention is obtained by slicing and polishing a silicon single crystal doped with a suitable amount of nitrogen, carbon and oxygen, contains a nitrogen concentration of 5×10¹⁴ to 1×10¹⁶/cm³, a carbon concentration of 1×10¹⁵ to 5×10¹⁶/cm³, and an oxygen concentration of 6×10¹⁷ to 11×10¹⁷/cm³.

The nitrogen concentration of the silicon substrate is in the range of 5×10¹⁴ to 1×10¹⁶/cm³, and preferably 1×10¹⁵ to 5×10¹⁵/cm³. It is indispensable to set the nitrogen concentration within the above range in order to obtain an annealed wafer having excellent Cu gettering capability, with a density of oxygen precipitates having a size of 10 nm to 120 nm in the range of ≧5×10¹¹/cm³, and a stacking fault density of ≧5×10⁸/cm³, by heat treatment in a subsequent device step. A nitrogen concentration below 5×10¹⁴/cm³ is too low, thus making the elimination of “grown-in faults” difficult. On the other hand, a nitrogen concentration over 1×10¹⁶/cm³ would make the growth of the single crystal difficult.

The carbon concentration of the silicon substrate is in the range of 1×10¹⁵ to 5×10¹⁶/cm³, and preferably 2×10¹⁵ to 1×10¹⁶/cm³. A carbon concentration below 1×10¹⁵/cm³ would not attain sufficient BMD density. On the other hand, a carbon concentration over 5×10¹⁶/cm³ would generate too low a number of stacking faults.

The oxygen concentration of the silicon substrate is in the range of 6×10¹⁷ to 11×10¹⁷/cm³ (JEIDA) and preferably 7×10¹⁷ to 10×10¹⁷/cm³. An oxygen concentration below 6×10¹⁷/cm³ would result in a small BMD size and also low density of BMD. On the other hand, an oxygen concentration over 10×10¹⁷/cm³ would result in too large a BMD size.

The method for adjusting the doping or the concentration of nitrogen, carbon and oxygen in growing a silicon single crystal by the CZ method is not especially limited. For example, nitrogen addition can be attained by using a wafer having a silicon nitride film formed on a silicon substrate added to the CZ melt; and carbon addition can be attained by immersing a carbon sheet into the molten silicon. Oxygen can be adjusted by crystal pulling conditions such as a crucible-rotating rate. However, the present invention should not be limited to these methods, and by utilizing conventionally known technology, as appropriate doping or concentration of nitrogen, carbon and oxygen can be adjusted during growth of the silicon single crystal.

The nitrogen concentration of the silicon substrate can be measured by SIMS (Secondary Ion Mass Spectrometry), while the carbon concentration and oxygen concentration can be measured by FT-IR (Fourier Transform Infrared Spectroscopy).

(b) Heat Treatment

In this step, the silicon substrate is subjected to heat treatment at a temperature of 650° C. to 800° C. for at least 4 hours. A heat treatment temperature below 650° C. would require too long a period of time for attaining a predetermined BMD density. On the other hand, a heat treatment temperature over 800° C. would not provide a sufficient BMD density. A heat treatment time below 4 hours would provide only a low BMD density. It should be noted that the upper limit of the heat treatment time is not especially limited, however, it is desirable to be equal to or shorter than 10 hours in view of cost.

In addition, the atmosphere of the heat treatment is not especially limited. An atmosphere containing nitrogen and oxygen may be desirable in view of preventing nitriding of wafer surface. Specifically, an atmosphere with an oxygen concentration of 0.1 to 1% by volume, and preferably 0.3 to 0.8% by volume, based on nitrogen gas is preferably used.

However, as in a second heat treatment to be described later, the low temperature heat treatment is also desirably carried out in an argon atmosphere. Annealing with argon gas at a high temperature needs to be carried out in the absence of an oxidized film. Therefore, substitution of an atmosphere containing nitrogen and oxygen with an argon atmosphere in the midst of transition from the heat treatment step to the annealing step is not desirable, in terms of removal of the oxidized film and the like, thus making a continuous treatment difficult.

The heat treatment according to the present invention is enough to satisfy at least the above requirements. Explanation will be given below on a typical embodiment of heat treatment conditions. It is natural that the present step should not be limited to these embodiments.

(b1) First Embodiment of Heat Treatment

The first embodiment of heat treatment comprises heat-treating a silicon substrate at a constant temperature T1 within the range of 650° C. to 800° C. for at least 4 hours in an atmosphere containing nitrogen and oxygen (first embodiment). In this embodiment, the method for heating to the constant temperature T₁ is not especially limited. For example, it may comprise heating to the constant temperature T₁ at a predetermined heating rate, after inserting the silicon substrate into a furnace in an atmosphere containing nitrogen and oxygen; or may comprise inserting the silicon substrate into a furnace already heated to the constant temperature T₁ to rapidly increase the temperature thereof. In this embodiment, it is desirable that a heating rate to the constant temperature T₁ is made slower, and a holding time t₁ is made longer, in terms of growth of oxygen deposit nuclei. From these view points, the heating rate from a starting temperature that is, the temperature when the silicon substrate is inserted, to the constant temperature T₁ is 0.1 to 2° C./minute, and preferably 0.3 to 1° C./minute. A heating rate below 1° C./minute would require an unduly long time to reach the constant temperature T₁, which is uneconomical. On the other hand, a heating rate over 2° C./minute would provide insufficient growth of oxygen deposit nuclei. The constant temperature T₁ in this embodiment is sufficient as long as it is in the range of 650° C. to 800° C. In addition, in this embodiment, the heat treatment may be completed by removing the silicon substrate from the furnace soon after holding it at the constant temperature T₁ for a predetermined time of at least 4 hours.

(b2) Second Embodiment of Heat Treatment

The second embodiment comprises continuously carrying out the heat treatment step and the annealing step. Specifically, it comprises heat-treating a silicon substrate at a constant temperature T₁ for predetermined time in an argon atmosphere as in the first embodiment, and thereafter subjecting the substrate to the annealing step at a high temperature in an argon atmosphere in a furnace, without removing the substrate from the furnace, or without decreasing furnace temperature. In the heat treatment according to this second embodiment, the heat treatment step and the annealing step may be carried out under an argon atmosphere, as described above.

Typical embodiments of the heat treatment step, wherein the heat treatment is carried out at a temperature of 650° C. to 800° C. for ≧4 hours have been described. However, the present invention should not be limited thereto. For example, heat treatments can be carried out in two or more stages; temperature may be increased or decreased arbitrarily, as long as it is in the range of 650° C. to 800° C.; or the heating rate or cooling rate in heating or cooling may be determined arbitrarily. In addition, heat treatment time is also not especially limited, as long as it is ≧4 hours in total. Further, the heat treatment may be carried out while continuously changing the temperature without maintaining at constant temperature.

(2) Annealing Step

After the heat treatment step as above, annealing with argon takes place at a temperature in the range of 1100° C. to 1250° C. By carrying out annealing with argon at a temperature in the range of 1100° C. to 1250° C., not only can oxygen precipitation nuclei having a size to be eliminated by heat treatment at a high temperature be grown sufficiently in advance to a size which cannot be eliminated, but also crystal faults in the surface layer can be eliminated.

As an atmosphere for annealing with argon, an argon gas with an argon concentration of 100% by volume may be typically used. Also, a mixed atmosphere of argon gas with hydrogen gas can be used. Usually, in preparation of an annealed wafer, annealing at high temperature can be carried out by using hydrogen gas and inert gas such as argon. In the present invention, annealing with argon is preferably used in view of cost.

In the annealing step, in the case where the heat treatment step is carried out according to the first embodiment, an oxidized film may be etched from the surface of the silicon substrate which has been removed from the furnace, and thereafter the substrate may be inserted into a furnace having an argon atmosphere. Alternatively, in the case where the heat treatment step is carried out according to the second embodiment, the silicon substrate which has been heat-treated in an argon atmosphere may be continuously placed in the furnace in an argon atmosphere, or transferred from the heat treatment furnace to a furnace for annealing. In this latter case, the silicon substrate, while being transferred outside the furnace, is desirably maintained in an argon atmosphere. Annealing with argon may be carried out at an annealing temperature T₂ in the range of 1100° C. to 1250° C. for an annealing time t₂ in the range of 5 minutes to 4 hours, and preferably at a temperature in the range of 1150° C. to 1250° C. for 10 minutes to 4 hours. An annealing temperature T₂ below 1100° C. would not eliminate “grown-in defects” on the surface. An annealing temperature T₂ over 1250° C. would dissolve precipitates of 1×10¹²/cm³. An annealing time t₂ below 5 minutes would provide insufficient elimination of “grown-in defects”, and an annealing time t₂ over 4 hours would reduce productivity.

(a) Annealing

The annealing treatment according to the present invention may be carried out by holding the silicon substrate at an annealing temperature T₂ within the range of 1100° C. to 1250° C. for a predetermined time t₂ in an argon atmosphere. The heating rate to the annealing temperature T₂ is desirably 4 to 10° C./minute at 650° C. to 1000° C., and 0.4 to 6° C./minute at 1000° C. to 1250° C. Preferably, the heating rate to the annealing temperature T₂ is 5 to 9° C./minute at 650° C. to 1000° C., and 0.5 to 5° C./minute at 1000° C. to 1250° C. A heating rate below 4° C./minute at 650° C. to 1000° C., or a heating rate below 0.4° C./minute at 1000° C. to 1250° C., would require an unduly long time to reach the above annealing temperature T₂, which is uneconomical. On the other hand, a heating rate over 10° C./minute at 650° C. to 1000° C., or the temperature increasing rate over 6° C./minute at 1000° C. to 1250° C. would be insufficient for growth of the oxygen precipitates or stacking faults.

In the case where the heat treatment step is carried out according to the second embodiment, the silicon substrate which has been heat-treated in an argon atmosphere may be continuously heated to the annealing temperature T₂ at a predetermined heating rate in the furnace in an argon atmosphere. Alternatively, the silicon substrate may be transferred from the heat treatment furnace to a furnace for annealing, and heated to the annealing temperature T₂ in an argon atmosphere and rapidly heated. In this case, the silicon substrate while being transferred outside the furnace, is desirably maintained in an argon atmosphere. Also in this embodiment, the heating rate to the annealing temperature T₂ is desirably selected to be 4 to 10° C./minute at 650° C. to 1000° C. and 0.4 to 6° C./minute at 1000° C. to 1250° C., and the annealing time t₂ is desirably selected to be 10 minutes to 4 hours, such that the concentration (density) of the oxygen precipitates with a size of 10 nm to 120 nm can be increased to a level ≧5×10¹¹/cm³, and stacking fault density can also be increased to a level ≧5×10⁸/cm³. From the above view points, it is desirable that the heating rate to the annealing temperature T₂ is 5 to 9° C./minute up to 1000° C., and 0.5 to 5° C./minute from 1000° C. to 1250° C. A heating rate below 4° C./minute up to 1000° C., or a heating rate below 0.4° C./minute from 1000° C. to 1250° C., would require a long time to reach the above annealing temperature T₂, which is uneconomical. On the other hand, a heating rate over 10° C./minute up to 1000° C., or a heating rate over 6° C./minute from 1000° C. to 1250° C. would be insufficient for growth of the oxygen precipitates or stacking faults.

In addition, in the annealing step according to the present invention, annealing may be completed by holding the silicon substrate (the annealed wafer) at the annealing temperature T₂ for the predetermined time t₂, cooling it down to a predetermined temperature T₃ at a cooling rate of 1 to 5° C./minute in the furnace in an argon atmosphere, and taking it out of the furnace.

In this case, the predetermined temperature T₃ may be in the range of 700 to 800° C. A predetermined temperature T₃ below 700° C. would require a long time. On the other hand, a predetermined temperature T₃ over 800° C. may generate slip in some cases. In addition, a cooling rate below 1° C./minute would require a long time, and a cooling rate of over 5° C./minute may generate slip in some cases.

The above embodiment is a typical embodiment of the annealing step for carrying out annealing with argon at a temperature of 1100° C. to 1250° C. The present invention, however, should not be limited thereto. For example, heating at an arbitrary rate is possible, as long as it is within the range of the above heating rates at each temperature region. For example, the heating rate up to the annealing temperature T₂ may be selected to be different values in 3 or more stages. Similarly, heating and cooling rates during heating or cooling may be determined arbitrarily. For example, as a cooling rate down to the predetermined temperature T₃ may be selected to be different values, for example in 2 or more stages. In addition, the annealing treatment with argon may be carried out by arbitrarily increasing or decreasing the annealing temperature T₂, as long as it is within the temperature range of 1100° C. to 1250° C., and it may be changed constantly without maintaining T₂ at a constant temperature. Also annealing time T₂ is arbitrary, as long as in the range of 10 minutes to 4 hours.

### (3) Internal Stacking Fault Density of Annealed Wafer

In the present invention, it is necessary that the internal stacking fault density is ≧5×10⁸/cm³ in the annealed wafer subjected to annealing, and it is desirable that the internal stacking fault density is in the range of 1×10⁹ to 1×10¹⁰/cm³. An internal stacking fault density after annealing below 5×10⁸/cm³ would provide only weak gettering capability. The internal stacking fault density after annealing can be measured with an optical microscope by cleaving an annealed wafer and subjecting the cleaved surface to light etching.

### II. Annealed Wafer

The silicon wafer (annealed wafer) relevant to the present invention is characterized in that oxygen precipitates with a size of 10 nm to 120 nm are present in a number ≧5×10¹¹/cm³ in a layer from the surface of a silicon wafer to a position equal to or deeper than 50 μm therefrom, and stacking fault density is ≧5×10⁸/cm³. By satisfying all of the above requirements, an annealed wafer can be provided which is capable of attaining an initial object of the present invention, enhancement of gettering effects to Cu, suppression of re-discharge of gettered Cu even in low temperature heat treatment in a device process, and enhancement of device reliability by preventing Cu contamination, in addition to its characteristics as an existing IG material. Therefore, it can be utilized suitably to produce high density, highly integrated devices such as highly-integrated MOS devices.

### Oxygen Precipitates

The silicon wafer (annealed wafer) of the present invention has oxygen precipitates with a size of 10 nm to 120 nm in a number of ≧5×10¹¹/cm³, and preferably 1×10¹² to 1×10¹³/cm³, in a layer ≧50 μm below the surface of the wafer. The oxygen precipitates with the above size in a number below 5×10¹¹/cm³ would provide weak slip resistance in processes such as RTA (Rapid-Thermal-Annealing). It should be noted that the upper limit of the density of oxygen precipitates is not especially limited. It is desirable to be ≦1×10¹³/cm³, because heat treatment at a low temperature for a long time would be required to increase the density.

A position equal to or deeper than 50 μm from the surface of a silicon wafer indicates more specifically a range from 50 μm to the center of the wafer. In the present invention, a reason for excluding regions near the surface down to less than 50 μm from the surface is that the oxygen precipitates or stacking fault density generated inside the wafer, which is sufficiently distant from the device region at the vicinity of the wafer surface, has gettering effects with respect to contamination by heavy metals. Therefore, in the present invention, the oxygen precipitates and stacking fault density at the position ≧50 μm from the surface of a silicon wafer, excluding the relevant range, are specified herein.

In addition, a reason for specifying a range of 10 nm to 120 nm as a size of the oxygen precipitates is that although oxygen precipitates with a size below 10 nm may be included in a large quantity in the annealed wafer of the present invention, it is necessary for the size of oxygen precipitates to be over 10 nm to measure the precipitation density with a transmission electron microscope (TEM). Oxygen precipitates with size below 10 nm cannot be measured by a TEM method, and therefore the relevant range (below 10 nm) is excluded. On the other hand, although the oxygen precipitates having the size of over 120 nm can be included in the annealed wafer of the present invention, precipitates having a size of over 120 nm provide small fault density, therefore the relevant range (>120 nm) is also excluded. Both smaller and larger precipitates may be present, however.

The oxygen precipitates can be measured by observing oxygen precipitates inside the silicon wafer with a transmission electron microscope, and counting oxygen precipitates with a size of 10 nm to 120 nm, at a position ≧50 μm from the surface of a silicon wafer. It should be noted that, as used herein, “size of oxygen precipitates” is defined as the length of a diagonal line of octahedral oxygen deposit observed with a transmission electron microscope.

### Stacking Fault Density

In the annealed wafer of the present invention, the stacking fault density is ≧5×10⁸/cm³, at a position 50 μm or more from the surface of the silicon wafer, and preferably 1×10⁹ to 1×10¹°/cm³. A stacking fault density below 5×10⁸/cm³ would provide weak gettering capability. It should be noted that the upper limit of the stacking fault density is not especially limited.

The stacking fault density of the annealed wafer of the present invention can be measured with an optical microscope by cleaving a silicon wafer, and subjecting the cross-sectional surface to light etching for 2 minutes.

The annealed wafer of the present invention can be produced by the above method for producing the annealed wafer relevant to the present invention.

### EXAMPLES

### Example 1

By using CZ method, a silicon single crystal containing a nitrogen concentration of 3×10¹⁵/cm³ (measured with SIMS), a carbon concentration of 8×10¹⁵/cm³, and an oxygen concentration of 9×10¹⁷/cm³ (measured with FT-IR according JEIDA standard) was pulled.

After slicing and polishing the resulting silicon single crystal to obtain a mirror wafer (a silicon substrate), inserting the mirror wafer into a furnace in an atmosphere containing nitrogen and oxygen, specifically, an atmosphere containing oxygen in a concentration of 0.2% by volume, based on nitrogen gas, at 700° C., the mirrored wafer was subjected to heat treatment at 700° C. for 4 hours, and then removed from the furnace.

An oxidized film on the silicon substrate having undergone heat treatment was removed by etching, the etched silicon substrate was inserted in a furnace in an argon atmosphere, specifically, 100% of argon gas. After it was heated at a heating rate of 8° C./minute from 700° C. to 1000° C., 4° C./minute from 1000° C. to 1100° C., and 1° C./minute from 1100° C. to 1200° C., annealing with argon was carried out at 1200° C. for 1 hour, the silicon substrate was subsequently removed from the furnace.

The inside oxygen precipitates after annealing were observed with a transmission electron microscope, to find that oxygen precipitates with a size of 10 nm to 120 nm were present in an amount of 1×10¹²/cm³, at a position ≧50 μm from the surface of the silicon wafer. In addition, the annealed wafer was cleaved and subjected to light etching for 2 minutes, to observe an area of a depth of 50 μm from the surface in a cross-sectional structure with an optical microscope. As a result, stacking fault density was found to be 5×10⁸/cm³.

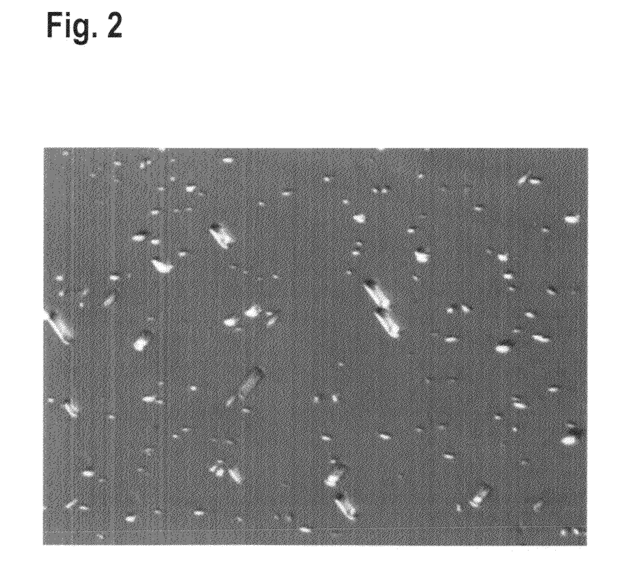

FIG. 2 is a photomicrograph showing a cross-section of the annealed wafer obtained in Example 1, at a depth of 100 μm from the surface. In the drawing, the oxygen precipitates are depicted as a small pit, and the stacking fault is depicted as a linear fault.

### Example 2

By using the CZ method, a silicon single crystal containing a nitrogen concentration of 2×10¹⁵/cm³ (measured with SIMS), a carbon concentration of 8×10¹⁵/cm³, and an oxygen concentration of 9×10¹⁷/cm³ (measured with FT-IR according JEIDA standard) was pulled.

After slicing and polishing the resulting silicon single crystal to obtain a mirror wafer (a silicon substrate), the mirror wafer was inserted into a furnace in an argon atmosphere, with an argon gas concentration of 100%. The mirrored wafer was held in the furnace at 700° C., for 4 hours. Then, it was subjected to annealing with argon at 1200° C. for 1 hour, by heating at a heating rate of 8° C./minute up to 1000° C., and subsequently after the temperature increase, by increasing the temperature at a heating rate of 4° C./minute up to 1100° C. and 1° C./minute up to 1200° C. The silicon substrate was subsequently removed from the furnace.

The inside oxygen precipitates after the annealing were observed with a transmission electron microscope, to find that oxygen precipitates with a size of 10 nm to 120 nm were present in an amount of 1×10⁹/cm³, at a position ≧50 μm from the surface of the annealed wafer (silicon wafer). In addition, the annealed wafer was cleaved and subjected to light etching for 2 minutes, to observe an area of a depth of 50 μm from the surface in cross-section with an optical microscope. As a result, stacking fault density was found to be 1×10⁷/cm³.

### Comparative Example 1

A silicon single crystal containing a nitrogen concentration of 1×10¹⁵ to 5×10¹⁵/cm³ (measured with SIMS), and an oxygen concentration of 7×10¹⁷ to 10×10¹⁷/cm³ (measured with FT-IR according JEIDA standard), without the addition of carbon, was pulled.

After inserting mirror wafer (a silicon substrate), obtained by slicing and polishing the resulting silicon single crystal, into a furnace under an argon atmosphere, specifically with an argon gas concentration of 100%, at an insertion temperature of 700° C., it was subjected to annealing under argon at 1200° C. for 1 hour, by heating at a heating rate of 8° C./minute up to 1000° C., 4° C./minute up to 1100° C. and 1° C./minute up to 1200° C., and then removed the furnace.

The inside oxygen precipitates after annealing were observed with a transmission electron microscope, to find that oxygen precipitates with a size of 10 nm to 120 nm were present in an amount of 1×10⁹/cm³, at a position ≧50 μm from the surface of the annealed wafer (silicon wafer). In addition, the annealed wafer was cleaved and subjected to light etching for 2 minutes, to observe an area of a depth of 50 μm from the surface in a cross-section with an optical microscope. As a result, stacking fault density was found to be 1×10⁷/cm³.

### A Method for Evaluation of Gettering

Cu contamination onto a wafer was carried out intentionally to evaluate gettering effects.

### Wafer Contamination

The silicon wafers (annealed wafers) obtained in Examples 1 to 2 and Comparative Example 1, were washed with ammonia-hydrogen peroxide water (APM)+a diluted HF aqueous solution (DHF)+hydrochloric acid-hydrogen peroxide water (HPM), to impart hydrophilicity to the surface thereof. Then, by using a spin coating method, the wafer surface was contaminated with Cu. The amount of Cu contaminated on the surface, determined by atomic absorption analysis, was found to be 4×10¹²/cm². For the treatment to diffuse the surface Cu inside the wafer, diffusion was carried out at 950° C. for 5 minutes in a nitrogen atmosphere. Cu was once gettered during cooling down to room temperature after the diffusion. Heat treatment was subsequently carried out at 400° C. for 2 hours in a nitrogen atmosphere to carry out re-discharging treatment from the gettering site. The amount of contamination was examined by atomic absorption analysis to determine the amount of Cu discharging to the surface. The amounts of Cu detected at the surface are shown in the following Table 1.

TABLE 1

| | Oxygen | | |
|---|---|---|---|
| | precipitates with | | Cu amount |
| | size of 10 to 120 nm | Stacking fault | detected at the |
| | (/cm³) | density (/cm³) | surface (/cm³) |
| Example 1 | 1 × 10¹² | 5 × 10⁸ | 5 × 10¹⁰ |
| Example 2 | 1 × 10¹² | 1 × 10⁹ | 4 × 10¹⁰ |
| Comparative | 1 × 10⁹ | 1 × 10⁷ | 4 × 10¹¹ |
| Example 1 | | | |

It was observed that Examples 1 and 2 showed a smaller amount of Cu detected at the surface, and higher gettering capability, in particular, a re-discharge suppression effect from the relevant gettering site for once gettered Cu, as compared with Comparative Example 1.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. An annealed silicon wafer containing oxygen precipitates with a size of 10 nm to 120 nm in a number ≧5×10¹¹/cm³, and a stacking fault density is ≧5×10⁸/cm³, both at a position equal to or deeper than 50 μm from the surface of the silicon wafer.

2. A method for producing an annealed wafer of claim 1, comprising heat treating a silicon substrate having a nitrogen concentration of 5×10¹⁴ to 1×10¹⁶/cm³, a carbon concentration of 1×10¹⁵ to 5×10¹⁶/cm³, and an oxygen concentration of 6×10¹⁷ to 11×10¹⁷/cm³ at a temperature of 650 to 800° C. for a time 4 hours to form a heat treated substrate, and
subjecting the heat treated substrate to argon annealing at a temperature of 1100 to 1250° C.,
wherein the internal stacking fault density after annealing is ≧5×10⁸/cm³.
